(19) United States
(12) Patent Application Publication
(10) Pub. No.: US 2022/0209440 A1
(43) Pub. Date: Jun. 30, 2022

(54) STRUCTURE OF CONNECTION OF CABLE AND CIRCUIT BOARD, ASSEMBLY METHOD, AND CONNECTOR

(71) Applicant: Amphenol AssembleTech(Xiamen) Co.,Ltd, Xiamen (CN)

(72) Inventors: Wenchu YANG, Xiamen (CN); David ROSENBOOM, Xiamen (CN); Jesus JARAMILLO, Xiamen (CN); Xiaodong WANG, Xiamen (CN); Shujian WANG, Xiamen (CN); Minjie ZHOU, Xiamen (CN); Hang LI, Xiamen (CN)

(73) Assignee: Amphenol AssembleTech(Xiamen) Co.,Ltd, Xiamen (CN)

(21) Appl. No.: 17/324,081

(22) Filed: May 18, 2021

(30) Foreign Application Priority Data
Dec. 31, 2020 (CN) 202011635756.5

(51) Int. Cl. H01R 12/62; H01R 43/00; H01R 43/02

(52) U.S. Cl. CPC H01R 12/62; H01R 43/02; H01R 43/005

(57) ABSTRACT

A structure of a connection of a cable and a circuit board, an assembly method, and a connector are provided. The structure of the connection of the cable and the circuit board is applied to connecting the cable and the circuit board. The cable is soldered onto the circuit board. The structure of the connection of the cable and the circuit board further includes a housing. The housing is mounted on the circuit board and covers bonding pads and/or non-bonding pad areas of the cable and the circuit board. A clearance is reserved between the opposite sides of the housing and the cable, or the opposite sides of the housing and the cable are attached to each other, or a covering layer is padded between the opposite sides of the housing and the cable.

### CROSS REFERENCE TO THE RELATED APPLICATIONS

This application is based upon and claims priority to Chinese Patent Application No. 202011635756.5, filed on Dec. 31, 2020, the entire contents of which are incorporated herein by reference.

### TECHNICAL FIELD

The present invention relates to a structure of a connection of a cable and a circuit board, an assembly method, and a connector.

### BACKGROUND

Having been applied in various electronic devices, circuit boards are now ubiquitous. In order to minimize the attenuation in some circuit boards such as a printed circuit board (PCB) or a printed circuit board assembly (PCBA), the current method is to eliminate PCB traces by using cables to minimize the lengths of the PCB traces.

In practice, the cable is soldered onto the PCB, but soldering is not secure enough or the soldered joint peels away easily during subsequent use of the electrical product. In order to maintain the strength of the connection between the cable and the circuit board, a typical method is to fix the cable and the bonding pads by injection molding after soldering, or by using an adhesive. The introduction of the adhesive or injection molding, however, will seriously affect the impedance of the bonding pad area. In this case, even if the impedance of the bonding pad area is specially adjusted during design to minimize the reduction in the impedance of the bonding pad area, this method still fails to stabilize the impedance due to technological reasons and thus needs to be improved.

### SUMMARY

In view of the above-mentioned issues identified in the prior art, an objective of the present invention is to provide a technical solution to the problem that the soldering between the cable and the circuit board is insecure or the impedance is unstable.

The first aspect of the present invention provides a structure of a connection of a cable and a circuit board. The cable is soldered onto the circuit board. The structure of the connection of the cable and the circuit board further includes a housing. The housing is mounted on the circuit board and covers bonding pads and/or non-bonding pad areas of the cable and the circuit board. A clearance is reserved between the opposite sides of the housing and the cable, or the opposite sides of the housing and the cable are attached to each other, or a covering layer is padded between the opposite sides of the housing and the cable.

When the opposite sides of the housing and the cable are attached to each other, or when the covering layer is padded between the opposite sides of the housing and the cable, the housing tightly presses the cable and the circuit board to ensure a firm and secure connection between the cable and the circuit board. When a clearance is reserved between the opposite sides of the housing and the cable, the opposite main portions of the housing and the cable are not in contact. The housing is configured to prevent the cable from being dramatically bent away from the circuit board, thereby preventing the welding portion of the cable and the circuit board from being bent and damaged.

Preferably, the cable and the circuit board are further fixedly connected by an adhesive or a molding material. The adhesive or the molding material is applied to or arranged on the bonding pads of the cable and the circuit board.

Preferably, the adhesive or the molding material is applied to or arranged on the non-bonding pad areas of the cable and the circuit board.

Preferably, the housing covers the adhesive or the molding material. Optionally, the adhesive or the molding material is arranged on the outside of the housing, and the housing is configured to tightly press the joint between the cable and the circuit board, thereby preventing the cable from being bent away from the circuit board, or being pulled parallel to the circuit board. Optionally, when a clearance is reserved between the opposite sides of the housing and the cable, the housing prevents the cable from being dramatically bent away from the circuit board, thereby preventing the joint made of the adhesive or the molding material between the cable and the circuit board from being damaged.

Herein, the housing does not necessarily cover the bonding pads between the cable and the circuit board, but can also tightly press the cable or prevent the cable from being excessively bent.

Preferably, the non-bonding pad areas covered by the housing fall outside the bonding pads and the joint made of the adhesive or the molding material of the cable, that is, the bonding pads and the joint made of the adhesive or the molding material of the cable are located at one side of the housing, and one end of the cable freely extending relative to the circuit board is located at the other side of the housing.

In this case, the housing also functions to tightly press the cable, or prevent the cable at the joint made of the adhesive from being dramatically bent away from the circuit board.

Preferably, the covering layer is made of a low-dielectric constant material or an insulating material, and is configured to not only fix the cable and the circuit board, but also stabilize the impedance of the bonding pad without being affected by the dielectric constant of the material of the fixed bonding pad. The dielectric constant of the low-dielectric constant material is less than 2.3.

Preferably, the covering layer is made of foam, an adhesive or a molding material.

Preferably, the housing is mounted on the circuit board through welding, a fixed mounting structure or a snap-fit structure.

Preferably, both ends of the housing are bent towards the circuit board to form side plates. The end portion of the side plate is provided with a weld leg, and the weld leg is mounted on the circuit board through welding, the fixed mounting structure or the snap-fit structure.

Preferably, the end portion of the side plate is provided with a folding plate bent outward. The lower end face of the folding plate is attached to the circuit board. The folding plate is mounted on the circuit board through welding, the fixed mounting structure or the snap-fit structure.

Preferably, the housing is made of metal or rigid plastic.

Preferably, when the opposite sides of the housing and the cable are attached to each other, the housing is made of insulating plastic, or the inner side of the housing is made of plastic or covered with an insulating material.

Preferably, the housing is formed by a mesh plate or a hollow plate.

Preferably, the thickness of the clearance is more than 0.5 times the thickness of the cable.

Preferably, the circuit board is a ceramic circuit board, an alumina ceramic circuit board, an aluminum nitride ceramic circuit board, a wiring board, a printed circuit board assembly (PCBA), an aluminum substrate, a high-frequency board, a thick copper board, an impedance board, a printed circuit board (PCB), an ultra-thin wiring board, an ultra-thin circuit board or an ultra-thin printed circuit board.

The second aspect of the present invention provides an assembly method for the structure of the connection of the cable and the circuit board provided in the first aspect. The assembly method includes: soldering the cable onto the circuit board; applying the adhesive or the molding material to fixedly connect the non-bonding pad areas of the cable and the circuit board; mounting the housing on the circuit board, so that the housing covers the bonding pads and/or the non-bonding, pad areas of the cable and the circuit board; and reserving a clearance between the opposite sides of the housing and the cable, or attaching the opposite sides of the housing and the cable to each other, or padding a covering layer between the opposite sides of the housing and the cable.

The third aspect of the present invention provides a connector. The connector includes a circuit board and a cable, and the circuit board and the cable employ the structure of the connection of the cable and the circuit board provided in the first aspect.

The present invention has the following advantages.

1. The adhesive or the molding material and the housing are employed to jointly guarantee the stability of the joints of the bonding pads of the cable and the circuit board.

2. The opposite sides of the housing and the cable are attached to each other, or the covering layer is padded between the opposite sides of the housing and the cable, so that the housing tightly presses the cable and the circuit board to ensure a firm and secure connection between the cable and the circuit board.

3. A low-dielectric constant material serves as the covering layer, which not only fixes the cable and the circuit board, but also stabilizes the impedance of the bonding pad without being affected by the dielectric constant of the material of the fixed bonding pad.

4. When a clearance is reserved between the opposite sides of the housing and the cable, the opposite main portions of the housing and the cable are not in contact, and the housing functions to prevent the cable from being dramatically bent away from the circuit board, thereby preventing the welding portion of the cable and the circuit board from being bent and damaged.

5. The housing is configured to protect the bonding pad, while providing a dustproof function.

### BRIEF DESCRIPTION OF THE DRAWINGS

FIG. 1 is an exploded view of a structure of a connection of a cable and a circuit board.

FIG. 2 is a perspective view of the structure of the connection of the cable and the circuit board.

FIG. 3 is a front elevation view of the structure of the connection of the cable and the circuit board.

FIG. 4 is a side elevation view of the structure of the connection of the cable and the circuit board.

In the figures: 1, circuit board; 2, cable; 3, adhesive; 4, housing; and 5, covering layer.

### DETAILED DESCRIPTION OF THE EMBODIMENTS

In order to clarify the technical problems to be solved, technical solutions and advantages of the present invention, the present invention will be further described below in detail in conjunction with the drawings and embodiments. It should be understood that the specific embodiments described herein are used only to explain the present invention rather than to limit the present invention.

### Embodiment 1

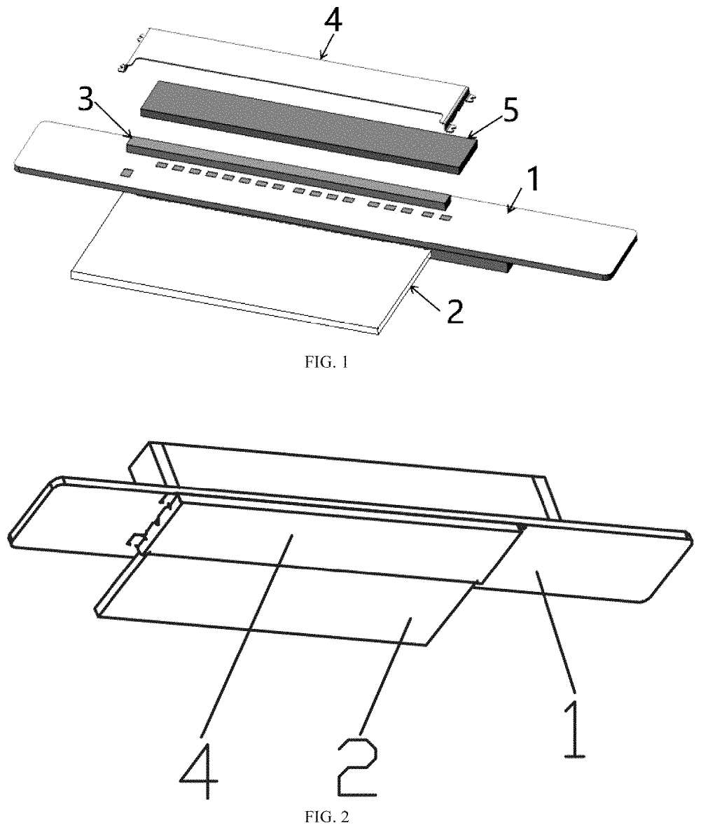

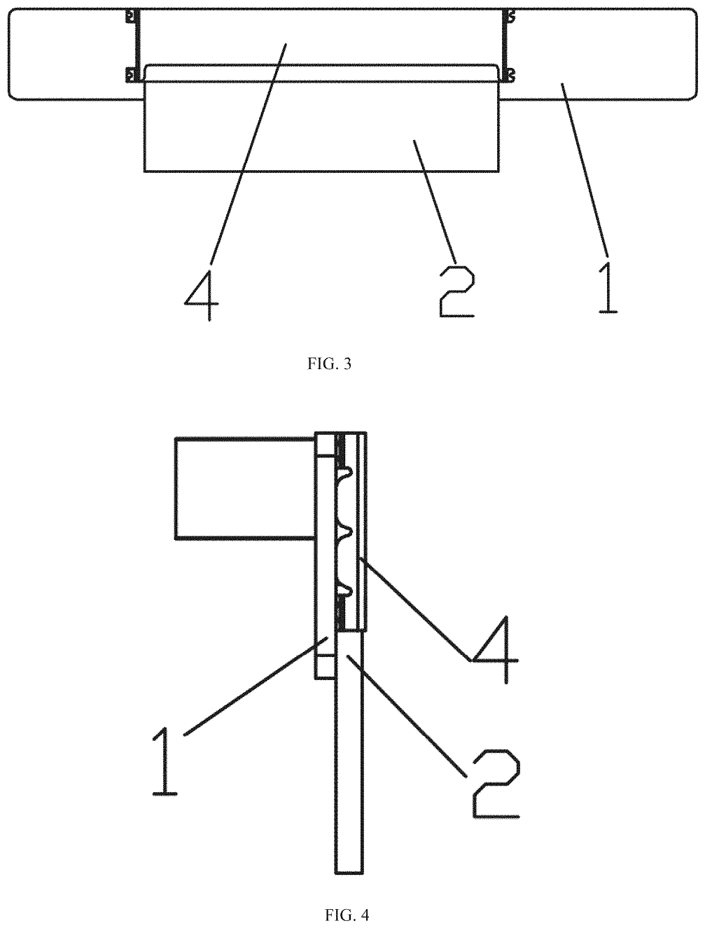

referring to FIGS. 1 to 4, a structure of a connection of a cable and a circuit board includes the circuit board 1, the cable 2, the adhesive 3 and the housing 4.

In the present embodiment, the cable 2 is a cable, and the circuit board 1 is a PCB. In other embodiments, the circuit board 1 may be a PCBA. In other embodiments, the adhesive 3 may be other molding materials.

In the present embodiment, the housing 4 is an integral and intact plate. In other embodiments, the housing 4 may also be formed by a mesh plate or a hollow plate, and is made of metal or rigid plastic.

Specifically, the cable 2 is soldered onto the circuit board 1.

The adhesive 3 or the molding material is applied to the non-bonding pad areas between the cable 2 and the circuit board 1 to further fixedly connect the cable 2 and the circuit board 1.

The housing 4 is mounted on the circuit board 1 and covers the bonding pads and the non-bonding pad areas between the cable 2 and the circuit board 1. In other embodiments, the housing 4 only covers the bonding pads between the cable 2 and the circuit board 1.

The opposite sides of the housing 4 and the cable 2 are attached to each other, or the covering layer 5 is padded between the opposite sides of the housing 4 and the cable 2, so that the housing 4 tightly presses the cable 2 and the circuit board 1 to ensure a firm and secure connection between the cable 2 and the circuit board 1.

When attached, the contact surfaces between the housing 4 and the cable 2 are covered with an insulating material or a low-dielectric constant material. The dielectric constant of the low-dielectric constant material is less than 2.3.

When the covering layer 5 is padded, the covering layer 5 is made of the low-dielectric constant material or the insulating material, and is configured to not only fix the cable 2 and the circuit board 1, but also stabilize the impedance of the bonding pad without being affected by the dielectric constant of the material of the fixed bonding pad. In the present embodiment, the covering layer 5 is made of foam. In other embodiments, the covering layer 5 may be formed from other materials.

In the present embodiment, both sides of the housing 4 are bent towards the circuit board 1 to form side plates, and the end portion of the side plate is provided with a folding plate bent outward. The lower end face of the folding plate is attached to the circuit board 1. The folding plate is mounted on the circuit board 1 through welding. In other embodiments, the folding plate may also be mounted through a fixed mounting structure or a snap-fit structure.

In the present invention, the adhesive 3 or the molding material and the housing 4 are employed to jointly guarantee the stability of the joints of the bonding pads of the cable 2 and the circuit board 1. The opposite sides of the housing 4 and the cable 2 are attached to each other, or the covering layer 5 is padded between the opposite sides of the housing 4 and the cable 2, so that the housing 4 tightly presses the cable 2 and the circuit board 1 to ensure a firm and secure connection between the cable 2 and the circuit board 1. The covering layer 5 is made of a low-dielectric constant material, and is configured to not only fix the cable 2 and the circuit board 1, but also stabilize the impedance of the bonding pad without being affected by the dielectric constant of the material of the fixed bonding pad.

### Embodiment 2

The difference between the present embodiment and Embodiment 1 is that in the present embodiment, a clearance is reserved between the housing 4 and the cable 2, that is, the opposite sides of the housing 4 and the cable 2 are not in contact. In the present embodiment, the thickness of the clearance is equal to the thickness of the cable 2.

The housing 4 is configured to prevent the cable 2 from being dramatically bent away from the circuit board 1, thereby preventing the welding portion of the cable 2 and the circuit board 1 from being bent and damaged.

### Embodiment 3

The difference between the present embodiment and Embodiment 1 or 2 is that in the present embodiment, the housing 4 only covers the joint made of the adhesive 3 between the cable 2 and the circuit board 1, but the housing 4 also functions to tightly press the cable 2 or prevent the cable 2 at the joint made of the adhesive 3 from being dramatically bent away from the circuit board 1. In this way, on one hand, the welding portion of the cable 2 and the circuit board 1 is prevented from being bent and damaged, and on the other hand, the size of the housing 4 is reduced, thereby diminishing the material cost and the weight of the circuit board.

### Embodiment 4

The difference between the present embodiment and Embodiment 1, 2 or 3 is that in the present embodiment, the areas covered by the housing 4 fall outside the welding portion and the joint made of the adhesive 3 between the cable 2 and the circuit board 1, that is, the welding portion and the joint made of the adhesive 3 are located at one end of the housing 4, while one end of the cable 2 freely extending relative to the circuit hoard 1 is located at the other end of the housing 4.

In this case, the housing 4 also functions to tightly press the cable 2, or prevent the cable 2 at the joint made of the adhesive 3 from being dramatically bent away from the circuit board 1.

### Embodiment 5

A connector employs the structure of the connection of the cable and the circuit board provided in the above embodiments.

The above embodiments are only used to illustrate the technical solutions of the present invention, rather than to limit the present invention. Although the present invention is described in detail with reference to the aforementioned embodiments, those having ordinary skill in the art should understand that modifications can be made to the technical solutions recorded in the aforementioned embodiments, or equivalent replacements can be made to some of the technical features. However, such modifications or replacements do not make the essence of the corresponding technical solutions deviate from the spirit and scope of the technical solutions of the embodiments of the present invention.

What is claimed is:

1. A structure of a connection of a cable and a circuit board, wherein the cable is soldered onto the circuit board;
the structure further comprises a housing, wherein the housing is mounted on the circuit board, and the housing covers bonding pads of the cable and the circuit board and/or non-bonding pad areas of the cable and the circuit board; and
a clearance is reserved between opposite sides of the housing and the cable, or the opposite sides of the housing and the cable are attached to each other, or a covering layer is padded between the opposite sides of the housing and the cable.

2. The structure according to claim 1, wherein
the cable and the circuit board are fixedly connected by an adhesive or a molding material;
the adhesive or the molding material is applied to or arranged on the non-bonding pad areas of the cable and the circuit board.

3. The structure according to claim 2, wherein
the housing covers the adhesive or the molding material; or the adhesive or the molding material is applied to or arranged on an outside of the housing.

4. The structure according to claim 2, wherein
the non-bonding pad areas covered by the housing fall outside the bonding pads and a joint of the cable, wherein the joint is made of the adhesive or the molding material, wherein
the bonding pads and the joint of the cable are located at a first side of the housing, and
an end of the cable is located at a second side of the housing, wherein the end of the cable freely extends relative to the circuit board.

5. The structure according to claim 1, wherein
the covering layer is a low-dielectric constant material or an insulating material, and a dielectric constant of the low-dielectric constant material is less than 2.3.

6. The structure according to claim 5, wherein
the covering layer is made of foam, an adhesive or a molding material.

7. The structure according to claim 1, wherein
the housing is mounted on the circuit board through welding, a fixed mounting structure or a snap-fit structure.

8. The structure according to claim 7, wherein
both ends of the housing are bent towards the circuit board to form side plates;
an end portion of each of the side plates is provided with a weld leg; and
the weld leg is mounted on the circuit board through the welding, the fixed mounting structure or the snap-fit structure.

9. The structure according to claim 1, wherein
when the opposite sides of the housing and the cable are attached to each other, the housing is made of insulating plastic, or an inner side of the housing is made of plastic, or the inner side of the housing is covered with an insulating material.

10. The structure according to claim 1, wherein
the circuit board is a printed circuit board assembly (PCBA) or a printed circuit board (PCB).

11. An assembly method for the structure of the connection of the cable and the circuit board according to claim 1, comprising:
soldering the cable onto the circuit board;
applying an adhesive or a molding material to fixedly connect the non-bonding pad areas of the cable and the circuit board;
mounting the housing on the circuit board, wherein the housing covers the bonding pads and/or the non-bonding pad areas of the cable and the circuit board; and
reserving the clearance between the opposite sides of the housing and the cable, or attaching the opposite sides of the housing and the cable to each other, or padding the covering layer between the opposite sides of the housing and the cable.

12. A connector, comprising a circuit hoard and a cable, wherein the circuit board and the cable employ the structure of the connection of the cable and the circuit board according to claim 1.

13. The assembly method according to claim 11, wherein
the cable and the circuit board are fixedly connected by the adhesive or the molding material;
the adhesive or the molding material is applied to or arranged on the non-bonding pad areas of the cable and the circuit board.

14. The assembly method according to claim 13, wherein
the housing covers the adhesive or the molding material; or the adhesive or the molding material is applied to or arranged on an outside of the housing.

15. The assembly method according to claim 13, wherein
the non-bonding pad areas covered by the housing fall outside the bonding pads and a joint of the cable, wherein the joint is made of the adhesive or the molding material, wherein
the bonding pads and the joint of the cable are located at a first side of the housing, and
an end of the cable is located at a second side of the housing, wherein the end of the cable freely extends relative to the circuit board.

16. The assembly method according to claim 11, wherein
the covering layer is a low-dielectric constant material or an insulating material and a dielectric constant of the low-dielectric constant material is less than 2.3.

17. The assembly method according to claim 16, wherein
the covering layer is made of foam, an adhesive or a molding material.

18. The assembly method according to claim 11, wherein
the housing is mounted on the circuit board through welding, a fixed mounting structure or a snap-fit structure.

19. The assembly method according to claim 18, wherein
both ends of the housing are bent towards the circuit board to form side plates;
an end portion of each of the side plates is provided with a weld leg; and
the weld leg is mounted on the circuit board through the welding, the fixed mounting structure or the snap-fit structure.

20. The assembly method according to claim 11, wherein
when the opposite sides of the housing and the cable are attached to each other, the housing is made of insulating plastic, or an inner side of the housing is made of plastic, or the inner side of the housing is covered with an insulating material.
